(19) United States
(12) Patent Application Publication
(10) Pub. No.: US 2015/0329356 A1
(43) Pub. Date: Nov. 19, 2015

(54) MEMS STRUCTURE AND METHOD OF MANUFACTURING THE SAME

(71) Applicant: SAMSUNG ELECTRO-MECHANICS CO., LTD., Suwon-Si (KR)

(72) Inventors: Jong Woo HAN, Suwon-Si (KR); Sun Ho KIM, Suwon-Si (KR); Heung Woo PARK, Suwon-Si (KR)

(21) Appl. No.: 14/711,454

(22) Filed: May 13, 2015

(30) Foreign Application Priority Data
May 13, 2014 (KR) 10-2014-0057374

(51) Int. Cl. B81C 1/00; B81B 3/00

(52) U.S. Cl. CPC B81C 1/00825; B81B 3/0072

(57) ABSTRACT

There are provided a micro electro mechanical systems (MEMS) structure and a method of manufacturing the same. The MEMS structure includes: a middle structure including an insulating layer, a circuit layer formed on the insulating layer, a mass formed beneath the insulating layer, and supports formed so as to be spaced apart from sides of the mass, and having corner portions of sides formed in a concave shape; an upper structure formed so as to enclose an upper portion of the middle structure; and a lower structure formed so as to enclose a lower portion of the middle structure.

### CROSS-REFERENCE TO RELATED APPLICATION

This application claims the benefit of Korean Patent Application No. 10-2014-0057374, filed on May 13, 2014, entitled “MEMS Structure and Method of Manufacturing the Same” which is hereby incorporated by reference in its entirety into this application.

### BACKGROUND

1. Field

The present disclosure relates to a micro electro mechanical systems (MEMS) structure and a method of manufacturing the same.

2. Description of Related Art

A micro electro mechanical systems (MEMS) is a technology of manufacturing a micro mechanical structure such as a very large scale integrated circuit, an inertial sensor, a pressure sensor, an oscillator, or the like, by processing silicon, crystal, glass, or the like. MEMS devices have a precision of a micrometer ( 1/1,000,000 meter) or less and may be structurally mass-produced as a micro product at a low cost by applying a semiconductor micro process technology of repeating processes such as a deposition process, an etching process, and the like.

As a sensor using the MEMS has been recently applied widely to recognition of various motions, and the like, in an acceleration sensor, a smart phone, a game machine, and the like, a demand for the sensor using the MEMS has increased.

Among the MEMS devices according to the related art, the inertial sensor includes a piezoelectric material disposed on a membrane in order to drive a mass or sense displacement of the mass. (U.S. Pat. No. 5,488,862)

### SUMMARY

An aspect of the present disclosure may provide a micro electro mechanical systems (MEMS) structure capable of decreasing a sawing load in a sawing process, and a method of manufacturing the same.

An aspect of the present disclosure may also provide an MEMS structure capable of decreasing a defect due to back side sawing in a sawing process, and a method of manufacturing the same.

An aspect of the present disclosure may also provide an MEMS structure capable of decreasing stress due to a sawing process, and a method of manufacturing the same.

According to an aspect of the present disclosure, an MEMS structure may include: a middle structure including an insulating layer, a circuit layer formed on the insulating layer, a mass formed beneath the insulating layer, and supports formed so as to be spaced apart from sides of the mass, and having corner portions of sides formed in a concave shape; an upper structure formed so as to enclose an upper portion of the middle structure; and a lower structure formed so as to enclose a lower portion of the middle structure.

According to another aspect of the present disclosure, a method of manufacturing an MEMS structure may include: preparing a middle substrate divided into a unit region and a sawing region; forming a circuit layer in the unit region on an upper surface of the middle substrate; forming a middle structure by patterning a lower surface of the middle substrate to form a mass and supports in a unit region and form a lower groove in the sawing region, the supports being formed so as to be spaced apart from both sides of the mass; forming an upper structure and a lower structure, the upper structure enclosing an upper portion of the middle structure and the lower structure enclosing a lower portion of the middle structure; and forming an MEMS structure in a unit by removing the middle structure, the upper structure, and the lower structure in the sawing region.

The forming of the circuit layer may further include forming an upper groove in an upper silicon layer in the sawing region.

In the forming of the middle structure, the mass, the supports, and the lower groove may be formed by patterning a lower silicon layer.

In the forming of the middle structure, the lower silicon layer may be patterned by a plasma etching process.

### BRIEF DESCRIPTION OF DRAWINGS

The above and other aspects, features and other advantages of the present disclosure will be more clearly understood from the following detailed description taken in conjunction with the accompanying drawings, in which:

FIGS. 1 and 2 are cross-sectional views showing a micro electro mechanical systems (MEMS) structure according to an exemplary embodiment of the present disclosure;

FIGS. 3 through 10 are views showing a method of manufacturing an MEMS structure according to an exemplary embodiment of the present disclosure;

FIGS. 11 through 13 are cross-sectional views taken along line C-D of FIG. 10; and

FIGS. 14 through 18 are views showing a method of manufacturing an MEMS structure according to another exemplary embodiment of the present disclosure.

### DESCRIPTION OF EMBODIMENT

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

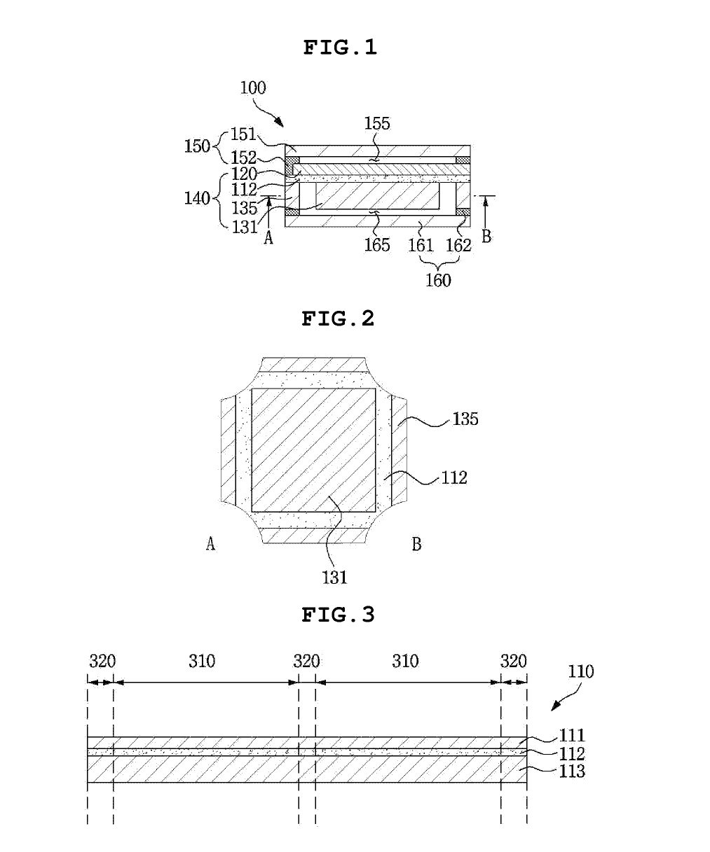

FIGS. 1 and 2 are cross-sectional views showing a micro electro mechanical systems (MEMS) structure according to an exemplary embodiment of the present disclosure.

Referring to FIG. 1, the MEMS structure 100 according to an exemplary embodiment of the present disclosure is configured to include a middle structure 140, an upper structure 150, and a lower structure 160.

The middle structure 140 according to an exemplary embodiment of the present disclosure may be formed in a plate shape and be bent so that a mass 131 may be displaced. The middle structure 140 may include an insulating layer 112, the mass 131, supports 135, and a circuit layer 120.

The insulating layer 112 according to an exemplary embodiment of the present disclosure may be formed of an oxide film such as SiO₂.

The mass 131 according to an exemplary embodiment of the present disclosure may be formed on a lower surface of the insulating layer 112. The mass 131 may be displaced by inertial force, external force, Coriolis force, driving force, or the like. The mass 131 according to an exemplary embodiment of the present disclosure may be formed in a cylindrical shape or a square pillar shape. However, the mass 131 is not limited to being formed in the above-mentioned shape, but may be formed in any shape known in the related art.

The supports 135 according to an exemplary embodiment of the present disclosure secure a space in which the mass 131 may move so that the mass 131 may be displaced. That is, the supports 135 are formed on a lower surface of the insulating layer 112 and support the insulating layer 112 so that the mass 131 may be displaced. For example, the supports 135 may be formed at both sides of the mass 131 and support the insulating layer 112 so that the mass 131 is spaced apart from the lower structure 160. Although not shown in FIG. 1, the supports 135 may be formed so as to enclose edges of the mass 131. However, the support 135 is not limited to being formed in the above-mentioned shape, but may be formed in any shape known in the related art.

The mass 131 and the supports 135 according to an exemplary embodiment of the present disclosure may be formed of a silicon wafer. However, the mass 131 and the supports 135 are not necessarily formed of the silicon wafer. The mass 131 and the supports 135 may be formed of any of the known materials used in an MEMS, such as a glass substrate.

The circuit layer 120 according to an exemplary embodiment of the present disclosure is formed on the insulating layer 112. The circuit layer 120 drives the mass 131 or senses displacement of the mass 131. For example, although not shown, an upper electrode, a lower electrode, and a piezoelectric material formed between the upper electrode and the lower electrode may be included in the circuit layer 120, which are obvious to those skilled in the art. A voltage may be applied to the piezoelectric material through the upper electrode and the lower electrode. When the voltage is applied to the piezoelectric material, an inverse piezoelectric effect that the piezoelectric material is expanded and contracted occurs in the piezoelectric material, such that the mass 131 may be driven. In addition, when stress is applied to the piezoelectric material, a piezoelectric effect that a voltage is generated in the upper electrode and the lower electrode may occur. The circuit layer 120 may sense the displacement of the mass 131 by the piezoelectric effect as described above.

According to an exemplary embodiment of the present disclosure, the upper structure 150 may be formed on the middle structure 140. The upper structure 150 may include an upper substrate 151 and a first adhesion layer 152.

According to an exemplary embodiment of the present disclosure, the upper substrate 151 may be formed of a silicon wafer. However, the upper substrate 151 is not necessarily formed of the silicon wafer. The upper substrate 151 may be formed of any of the known materials used in the MEMS, such as a glass substrate.

According to an exemplary embodiment of the present disclosure, the first adhesion layer 152 is formed on a lower surface of the upper substrate 151. In addition, the first adhesion layer 152 may be formed at an edge portion of the upper substrate 151. The first adhesion layer 152 formed as described above is adhered to an upper surface of the middle structure 140 to adhere the upper structure 150 and the middle structure 140 to each other. For example, the first adhesion layer 152 may be adhered to a portion of the circuit layer 120 of the middle structure 140. The first adhesion layer 152 may be formed of an insulating material having adhesion among materials known in an MEMS field.

According to an exemplary embodiment of the present disclosure, the first adhesion layer 152 may be formed so as to have any thickness. Here, any thickness may be a thickness enough to form a space in which the mass 131 may be displaced when the upper structure 150 and the middle structure 140 are adhered to each other. That is, the upper structure 150 may be a structure having an upper cavity 155 formed on a lower surface thereof by the first adhesion layer 152. In addition, the upper cavity 155 may be positioned above the circuit layer 120 and the mass 131 of the middle structure 140.

According to an exemplary embodiment of the present disclosure, the lower structure 160 may be formed beneath the middle structure 140. The lower structure 160 may include a lower substrate 161 and a second adhesion layer 162.

According to an exemplary embodiment of the present disclosure, the lower substrate 161 may be formed of a silicon wafer. However, the lower substrate 161 is not necessarily formed of the silicon wafer. The lower substrate 161 may be formed of any of the known materials used in the MEMS, such as a glass substrate.

According to an exemplary embodiment of the present disclosure, the second adhesion layer 162 is formed on an upper surface of the lower substrate 161. In addition, the second adhesion layer 162 may be formed at an edge portion of the lower substrate 161. The second adhesion layer 162 formed as described above may be adhered to a lower surface of the middle structure 140 to adhere the lower structure 160 and the middle structure 140 to each other. For example, the second adhesion layer 162 may be adhered to a lower surface of the support 135 of the middle structure 140. The second adhesion layer 162 may be formed of an insulating material having adhesion among materials known in an MEMS field.

According to an exemplary embodiment of the present disclosure, the second adhesion layer 162 may be formed so as to have any thickness. Here, any thickness may be a thickness enough to form a space in which the mass 131 may be displaced when the lower structure 160 and the middle structure 140 are adhered to each other. That is, the lower structure 160 may be a structure having a lower cavity 165 formed on an upper surface thereof by the second adhesion layer 162. In addition, the lower cavity 165 may be positioned below the circuit layer 120 and the mass 131 of the middle structure 140.

The upper structure 150 and the lower structure 160 according to an exemplary embodiment of the present disclosure formed as described above are formed in order to protect the middle structure 140. Although the case in which the cavities are formed in the upper structure 150 and the lower structure 160 by the first adhesion layer 152 and the second adhesion layer 162, respectively, has been described by way of example in the present disclosure, the present disclosure is not limited thereto. For example, the cavities may be directly formed in the upper substrate 151 and the lower substrate 161, respectively, to form the upper structure 150 and the lower structure 160.

FIG. 2 is a cross-sectional view of the MEMS structure taken along line A-B of FIG. 1.

A cross section taken along line A-B according to an exemplary embodiment of the present disclosure is a cross section of a lower half of the middle structure 140.

As shown in FIG. 2, the cross section of the lower half of the middle structure 140 may have a form in which corner portions thereof are roundly dug. In an exemplary embodiment of the present disclosure, the structure as described above may be derived by removing portions of a sawing region 320 in advance when the middle structure 140 is formed.

FIGS. 3 through 10 are views showing a method of manufacturing an MEMS structure according to an exemplary embodiment of the present disclosure.

Referring to FIG. 3, a middle substrate 110 is provided.

According to an exemplary embodiment of the present disclosure, the middle substrate 110 may be a silicon on insulator (SOI) wafer in which an upper silicon layer 111, an insulating layer 112, and a lower silicon layer 113 are sequentially formed. Here, the insulating layer 112 may be an oxide film such as SiO₂.

Although the case in which the middle substrate 110 is the SOI wafer has been described by way of example in the present disclosure, the present disclosure is not limited thereto. That is, the middle substrate 110 may be any kind of wafer used in the MEMS.

In addition, the middle substrate 110 according to an exemplary embodiment of the present disclosure may include a unit region 310 and a sawing region 320. The unit region 310 is a region in which the MEMS structure 100 is formed. In addition, the sawing region 320 may be formed at an outer side of the unit region 310. The sawing region 320 may be removed in performing a sawing process in order to separate the MEMS structure 100 into units later.

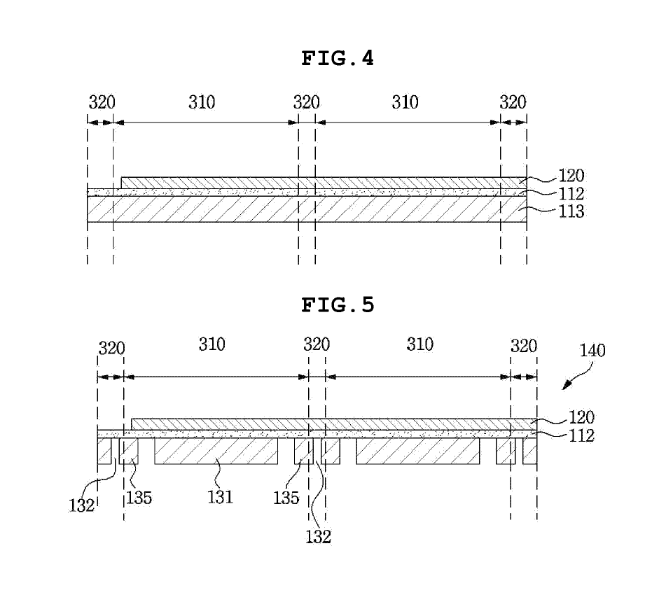

Referring to FIG. 4, the circuit layer 120 is formed on the middle substrate 110.

According to an exemplary embodiment of the present disclosure, the circuit layer 120 may be formed on the upper silicon layer 111 formed on the insulating layer 112. In addition, the circuit layer 120 may be formed in the unit region 310. The circuit layer 120 may be formed in order to drive a mass (not shown) to be formed later or sense displacement of the mass. For example, although not shown, an upper electrode, a lower electrode, and a piezoelectric material formed between the upper electrode and the lower electrode may be included in the circuit layer 120, which are obvious to those skilled in the art.

The circuit layer 120 according to an exemplary embodiment of the present disclosure is formed using a method known in the MEMS field, and a structure of the circuit layer 120 and a method of forming the circuit layer 120 are not particularly limited.

Referring to FIG. 5, the mass 131, a lower groove 132, and the supports 135 are formed.

According to an exemplary embodiment of the present disclosure, the mass 131, the lower groove 132, and the supports 135 are formed by a patterning process of removing portions of a lower surface of the middle substrate 110. For example, the mass 131, the lower groove 132, and the supports 135 may be formed by patterning the lower silicon layer 113.

According to an exemplary embodiment of the present disclosure, the mass 131 is formed in the unit region 310. That is, the circuit layer 120 is positioned on the mass 131. According to an exemplary embodiment of the present disclosure, the mass 131 may be formed by patterning the lower silicon layer 113 so that the insulating layer 112 of the middle substrate 110 is exposed. For example, the mass 131 may be formed in a cylindrical shape or a square pillar shape. However, the mass 131 is not limited to being formed in the above-mentioned shape, but may be formed in any shape known in the related art. In addition, a depth at which the lower silicon layer 113 is removed in order to form the mass 131 may be changed by those skilled in the art. The mass 131 formed as described above may be displaced by inertial force, external force, Coriolis force, driving force, or the like.

According to an exemplary embodiment of the present disclosure, the lower groove 132 is formed in the sawing region 320. According to an exemplary embodiment of the present disclosure, the lower groove 132 may be formed so as to include at least a portion of the sawing region 320. For example, the lower groove 132 may be formed so as to be positioned in the sawing region 320, as shown in FIG. 5. That is, the lower groove shown in FIG. 5 may be formed so as to have a width smaller than that of the sawing region 320. However, a structure of the lower groove 132 is not limited thereto.

According to an exemplary embodiment of the present disclosure, the lower groove 132 may be formed so as to expose the insulating layer 112. However, a depth of the lower groove 132 is not limited thereto. The depth of the lower groove 132 may be changed by those skilled in the art. Although the case in which one lower groove 132 is formed in one sawing region 320 has been shown in FIG. 5, the present disclosure is not limited thereto. A plurality of lower grooves 132 may be formed in one sawing region 320 depending on selection of those skilled in the art.

The support 135 according to an exemplary embodiment of the present disclosure may be formed over portions of the unit region 310 and the sawing region 320. That is, the support 135 may be formed in a portion of the unit region 310 and in the sawing region 320 adjacent to the corresponding unit region 310.

In addition, the supports 135 may be formed at both sides of the mass 131 and support the insulating layer 112 so that the mass 131 is spaced apart from the lower structure 160. The space in which the mass 131 may move so that the mass 131 may be displaced may be secured by the supports 135 formed as described above. Although not shown in FIG. 5, the supports 135 may be formed so as to enclose edges of the mass 131. However, the support 135 is not limited to being formed in the above-mentioned shape, but may be formed in any shape known in the related art.

According to an exemplary embodiment of the present disclosure, the mass 131, the lower groove 132, and the support 135 may be formed by performing plasma etching. In addition, the mass 131, the lower groove 132, and the support 135 may be simultaneously formed. That is, since the lower groove 132 may be formed by the same process as a process of forming the mass 131, the lower groove 132 may be formed without a separate additional process. That is, in the middle structure 140 according to an exemplary embodiment of the present disclosure, a thickness of a chipped portion may be decreased without a separate additional process.

As described above, the mass 131, the lower groove 132, and the circuit layer 120 are formed in the middle substrate 110, such that the middle structure 140 according to an exemplary embodiment of the present disclosure may be formed. For example, the middle structure 140 may perform the following operation. A voltage may be applied to the piezoelectric material through the upper electrode and the lower electrode of the circuit layer 120. When the voltage is applied to the piezoelectric material, an inverse piezoelectric effect that the piezoelectric material is expanded and contracted occurs in the piezoelectric material, such that the mass 131 may be driven. In addition, when stress is applied to the piezoelectric material, a piezoelectric effect that a voltage is generated in the upper electrode and the lower electrode may occur. The circuit layer 120 may sense the displacement of the mass 131 by the piezoelectric effect as described above.

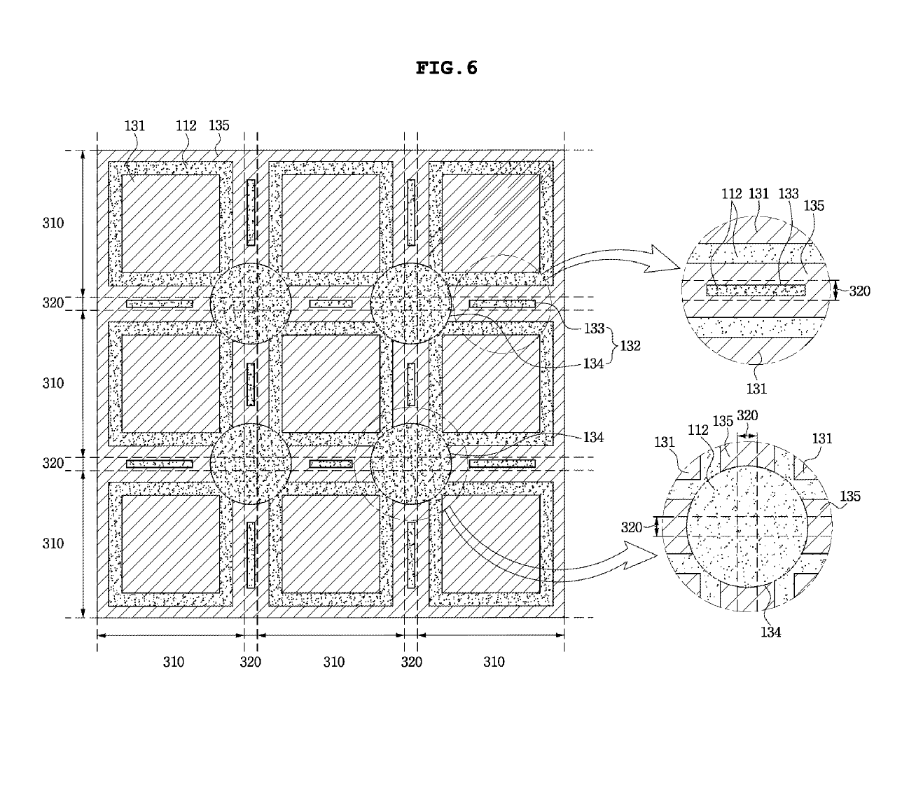

FIGS. 6 through 8 are views showing lower grooves according to exemplary embodiments of the present disclosure.

Referring to FIG. 6, a lower groove 132 according to a first exemplary embodiment of the present disclosure may include a first lower groove 133 and a second lower groove 134.

The first lower groove 133 according to a first exemplary embodiment of the present disclosure may be formed between two unit regions 310. In addition, referring to FIG. 6, the first lower groove 133 may be formed so as to be positioned only in the sawing region 320. That is, according to a first exemplary embodiment of the present disclosure, the first lower groove 133 may have a width smaller than that of the sawing region 320.

In addition, the second lower groove 134 according to a first exemplary embodiment of the present disclosure may be formed at a portion at which a plurality of sawing regions 320 intersect with each other. That is, the second lower groove 134 may be formed so as to include all of corners of a plurality of unit regions 310, as shown in FIG. 6.

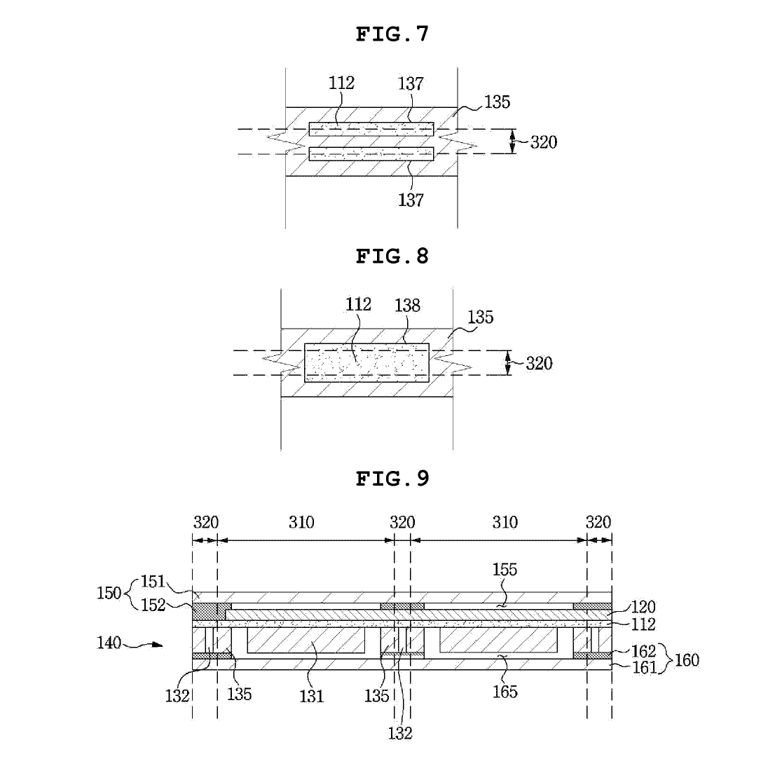

FIG. 7 is a view showing a first lower groove 137 according to a second exemplary embodiment of the present disclosure.

The number of first lower grooves 137 according to a second exemplary embodiment of the present disclosure may be plural. In addition, as shown in FIG. 7, the first lower grooves 137 according to a second exemplary embodiment of the present disclosure may be formed so as to include portions of the sawing regions 320. As shown in FIG. 7, according to a second exemplary embodiment of the present disclosure, two first lower grooves 137 may be formed in parallel with each other so as to include both sides of the sawing regions 320, respectively. Although the case in which two first lower grooves 137 are formed has been shown in FIG. 7, the present disclosure is not limited thereto. That is, the number of first lower grooves 137 and positions of the first lower grooves 137 may be changed depending on selection of those skilled in the art as long as positions at which the first lower grooves 137 are formed include the entirety or portions of the sawing regions 137.

FIG. 8 is a view showing a first lower groove 138 according to a third exemplary embodiment of the present disclosure.

The first lower groove 138 according to a third exemplary embodiment of the present disclosure may be formed at an outer portion of the sawing region 320 as well as at an inner portion of the sawing region 320. That is, according to a third exemplary embodiment of the present disclosure, the first lower groove 138 may have a width larger than that of the sawing region 320.

Structures of the lower grooves 132 of FIGS. 6 through 8 are only an example, and the lower grooves 132 are not limited to having these structures. The lower grooves 132 are formed in order to decrease a sawing load when performing a sawing process later, and the structures of the lower grooves 132 may be easily changed by those skilled in the art as long as the lower grooves 132 are formed so as to include at least portions of the sawing regions 320.

Referring to FIG. 9, the upper structure 150 and the lower structure 160 are formed.

According to an exemplary embodiment of the present disclosure, the upper structure 150 is formed on the middle structure 140, and the lower structure 160 is formed beneath the middle structure 140.

According to an exemplary embodiment of the present disclosure, the upper structure 150 may include the upper substrate 151 and the first adhesion layer 152.

According to an exemplary embodiment of the present disclosure, the upper substrate 151 may be formed of a silicon wafer. However, the upper substrate 151 is not necessarily formed of the silicon wafer. The upper substrate 151 may be formed of any of the known materials used in the MEMS, such as a glass substrate.

According to an exemplary embodiment of the present disclosure, the first adhesion layer 152 may be formed on the lower surface of the upper substrate 151. The first adhesion layer 152 may be adhered to the upper surface of the middle structure 140 to adhere the upper structure 150 and the middle structure 140 to each other. In addition, the first adhesion layer 152 may be formed in the sawing region 320 and the unit region 310 adjacent to the sawing region 320. The first adhesion layer 152 may be formed in a portion of the unit region 310 in order to maintain adhesion between the middle structure 140 and the upper structure 150 when the sawing region 320 is removed later. For example, the first adhesion layer 152 may be formed at the sawing region 320 and an edge portion of the unit region 310. The first adhesion layer 152 is formed at the edge portion of the unit region 310, such that it may also be formed on a portion of the circuit layer 120. The first adhesion layer 152 may be formed of an insulating material having adhesion among materials known in an MEMS field.

According to an exemplary embodiment of the present disclosure, the first adhesion layer 152 may be formed so as to have any thickness. Here, any thickness may be a thickness enough to form a space in which the mass 131 may be displaced when the upper structure 150 and the middle structure 140 are adhered to each other. That is, the upper structure 150 may be a structure having an upper cavity 155 formed on a lower surface thereof by the first adhesion layer 152. In addition, the upper cavity 155 may be positioned above the circuit layer 120 and the mass 131 of the middle structure 140.

According to an exemplary embodiment of the present disclosure, the lower structure 160 may include the lower substrate 161 and the second adhesion layer 162.

According to an exemplary embodiment of the present disclosure, the lower substrate 161 may be formed of a silicon wafer. However, the lower substrate 161 is not necessarily formed of the silicon wafer. The lower substrate 161 may be formed of any of the known materials used in the MEMS, such as a glass substrate.

According to an exemplary embodiment of the present disclosure, the second adhesion layer 162 is formed on an upper surface of the lower substrate 161. The second adhesion layer 162 may be adhered to the lower surface of the middle structure 140 to adhere the lower structure 160 and the middle structure 140 to each other. In addition, the second adhesion layer 162 may be formed in the sawing region 320 and the unit region 310 adjacent to the sawing region 320. The second adhesion layer 162 may be formed in a portion of the unit region 310 in order to maintain adhesion between the middle structure 140 and the lower structure 160 when the sawing region 320 is removed later. For example, the second adhesion layer 162 may be formed at the sawing region 320 and an edge portion of the unit region 310. The second adhesion layer 162 formed as described above may be adhered to the lower surface of the support 135 of the middle structure 140 formed in the sawing region 320 and the unit region 310. The second adhesion layer 162 may be formed of an insulating material having adhesion among materials known in an MEMS field.

According to an exemplary embodiment of the present disclosure, the second adhesion layer 162 may be formed so as to have any thickness. Here, any thickness may be a thickness enough to form a space in which the mass 131 may be displaced when the lower structure 160 and the middle structure 140 are adhered to each other. That is, the lower structure 160 may be a structure having a lower cavity 165 formed on an upper surface thereof by the second adhesion layer 162. In addition, the lower cavity 165 may be positioned below the circuit layer 120 and the mass 131 of the middle structure 140.

The upper structure 150 and the lower structure 160 according to an exemplary embodiment of the present disclosure formed as described above may be formed in order to protect the middle structure 140. Although the case in which the cavities are formed in the upper structure 150 and the lower structure 160 by the first adhesion layer 152 and the second adhesion layer 162, respectively, has been described by way of example in the present disclosure, the present disclosure is not limited thereto. For example, the cavities may be directly formed in the upper substrate 151 and the lower substrate 161, respectively, to form the upper structure 150 and the lower structure 160.

The upper structure 150 and the lower structure 160 are formed on and beneath the middle structure 140, respectively, as described above, such that a plurality of MEMS structures 100 connected to each other through the sawing regions 320 may be formed.

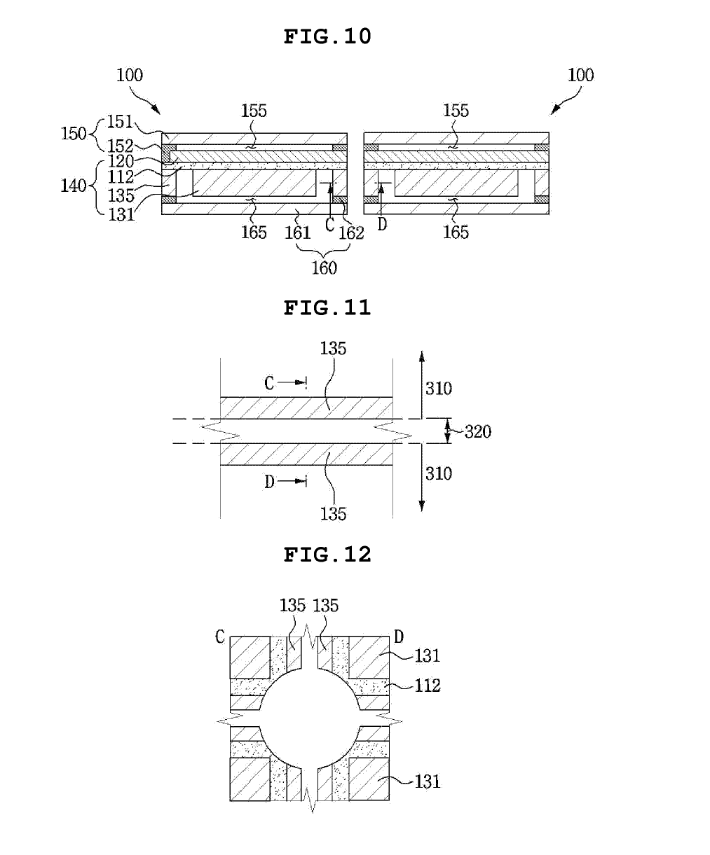

Referring to FIG. 10, MEMS structures 100 are formed in a unit.

According to an exemplary embodiment of the present disclosure, a sawing process of sawing the middle structure 140, the upper structure 150, and the lower structure 160 positioned in the sawing region 320 is performed. The sawing region 320 is removed by the sawing process. Therefore, the plurality of MEMS structures 100 connected to each other are separated into the MEMS structures 100 in a unit.

Since the lower groove 132 of the middle structure 140 is formed so as to include a portion of the sawing region 320 in the sawing process, a thickness of a portion of the sawing region 320 is decreased. Therefore, a load applied to a sawing blade performing the sawing process may be decreased, such that a defect due to back side sawing may be decreased. In addition, a thickness of the chipped portion is decreased, such that stress applied to the MEMS structure by the sawing process may be decreased.

In addition, according to an exemplary embodiment of the present disclosure, although not shown, pollution of a pad may be prevented. Here, the pad (not shown) is formed for wiring of the MEMS structure 100. According to the related art, the pad (not shown) is formed before the sawing process, and a plasma etching process is performed, in order to decrease a sawing load. In this case, the pad (not shown) is polluted and corroded by a plasma gas, such that a defect may occur at the time of wiring. However, according to an exemplary embodiment of the present disclosure, since the pad (not shown) is formed after the plasma etching process is performed, the defect due to the plasma gas may be prevented.

FIGS. 11 through 13 are cross-sectional views taken along line C-D of FIG. 10.

According to an exemplary embodiment of the present disclosure, FIGS. 11 through 13 show a cross section taken along line A-B of FIGS. 6 through 8 after a sawing process is performed.

According to an exemplary embodiment of the present disclosure, a cross section taken along line C-D of FIG. 10 after a sawing process is performed when the first lower groove 133 and the second lower groove 134 of FIG. 6 are formed may be confirmed from FIGS. 11 and 12.

When the sawing process is performed so that the first lower groove 133 has the width smaller than that of the sawing region 320 in FIG. 6, a structure in which sides of two unit regions 310 are in parallel with each other may be formed, as shown in FIG. 11.

In addition, when the sawing process is performed on a portion in which the second lower groove 134 is formed, a structure in which the second lower groove 134 and the removed sawing region 320 are connected to each other may be formed, as shown in FIG. 12.

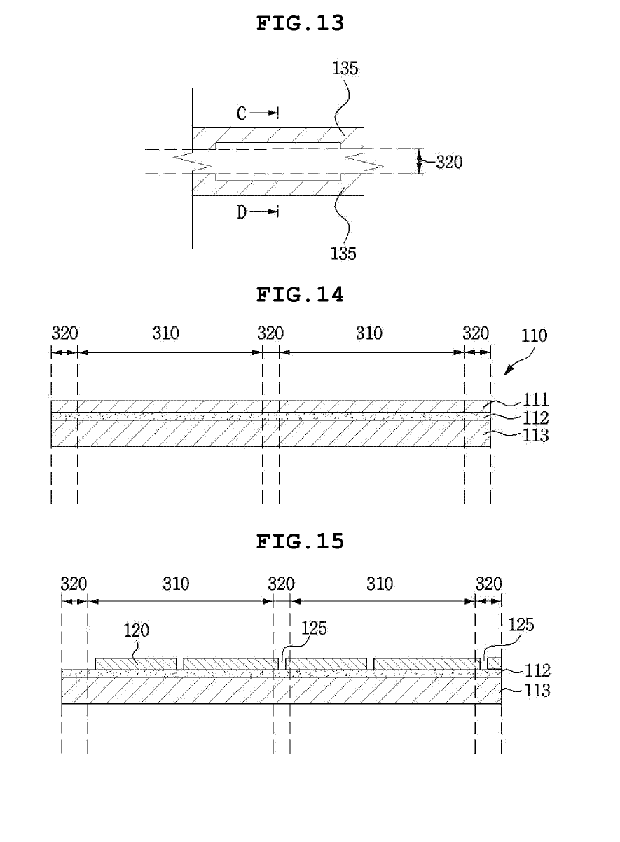

According to an exemplary embodiment of the present disclosure, a cross section taken along line C-D of FIG. 10 after a sawing process is performed when the first lower groove 133 of FIGS. 7 and 8 is formed may be confirmed from FIG. 13. Since both sides of the first lower groove 133 are positioned at an outer portion of the sawing region 320 in both of FIGS. 7 and 8, when the sawing process is performed, the cross section as shown in FIG. 13 may be confirmed.

As confirmed from FIGS. 11 through 13, structures of lateral cross sections of the middle structure 140 after the sawing process is performed may be changed depending on structures of the first and second lower grooves 133 and 134.

FIGS. 14 through 18 are views showing a method of manufacturing an MEMS structure according to another exemplary embodiment of the present disclosure.

Referring to FIG. 14, a middle substrate 110 is provided.

The middle substrate 110 according to another exemplary embodiment of the present disclosure is the same as the middle substrate 110 of FIG. 3. Therefore, a detailed description for the middle substrate 110 according to another exemplary embodiment of the present disclosure will be omitted.

Referring to FIG. 15, the circuit layer 120 and an upper groove 125 are formed on the middle substrate 110.

According to another exemplary embodiment of the present disclosure, the circuit layer 120 and the upper groove 125 may be formed on the upper silicon layer 111 formed on the insulating layer 112.

According to another exemplary embodiment of the present disclosure, the circuit layer 120 is formed in the unit region 310. The circuit layer 120 is formed in order to drive a mass (not shown) to be formed later or sense displacement of the mass. For example, although not shown, an upper electrode, a lower electrode, and a piezoelectric material formed between the upper electrode and the lower electrode may be included in the circuit layer 120, which are obvious to those skilled in the art.

The upper groove 125 according to another exemplary embodiment of the present disclosure is formed in the sawing region 320. According to another exemplary embodiment of the present disclosure, the upper groove 125 may be formed so as to include at least a portion of the sawing region 320.

According to another exemplary embodiment of the present disclosure, the upper groove 125 may be formed by removing a portion of an upper surface of the middle substrate 110. According to another exemplary embodiment of the present disclosure, the upper groove 125 may be formed so as to expose the insulating layer 112 of the middle substrate 110. However, a depth of the upper groove 125 is not limited thereto. The depth of the upper groove 125 may be changed by those skilled in the art.

As shown in FIG. 15, the upper groove 125 may be formed in the sawing region 320 and may be formed so as to have a width smaller than that of the sawing region 320. However, the structure of the upper groove 125 as described above is only an example, and is not limited thereto. For example, the upper groove 125 may be formed so as to have a width larger than that of the sawing region 320 or a plurality of upper grooves 125 may be formed. As described above, the structure of the upper groove 125 and the number of upper grooves 125 may be changed depending on selection of those skilled in the art as long as a thickness of a chipped portion may be decreased when a sawing process is performed later.

The circuit layer 120 and the upper groove 125 according to another exemplary embodiment of the present disclosure are formed using a method known in the MEMS field, and structures of the circuit layer 120 and the upper groove 125 and a method of forming the circuit layer 120 and the upper groove 125 are not particularly limited. In addition, the circuit layer 120 and the upper groove 125 may be simultaneously formed. That is, when an etching process is performed in order to form the circuit layer 120, the upper groove 125 may be formed together with the circuit layer 120. That is, since the upper groove 125 may be formed by the same process as a process of forming the circuit layer 120, the upper groove 125 may be formed without a separate additional process.

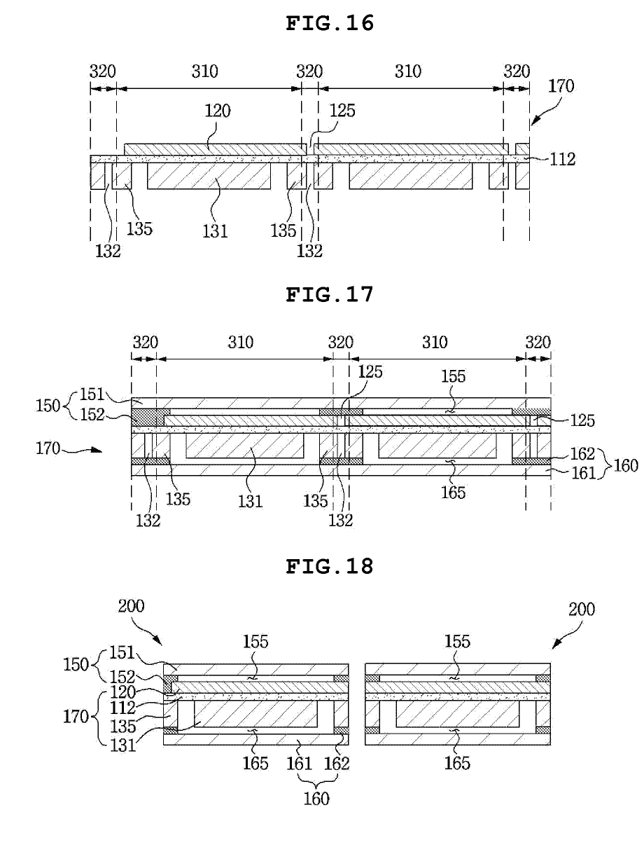

Referring to FIG. 16, the mass 131, a lower groove 132, the supports 135 are formed.

According to another exemplary embodiment of the present disclosure, the mass 131, the lower groove 132, and the supports 135 may be formed by a patterning process of removing portions of a lower surface of the middle substrate 110. For example, the mass 131, the lower groove 132, and the supports 135 may be formed by patterning the lower silicon layer 113.

See FIG. 5 with respect to a description for the mass 131, the lower groove 132, and the supports 135 according to another exemplary embodiment of the present disclosure.

As described above, the mass 131, the upper groove 125, the lower groove 132, and the circuit layer 120 are formed in the middle substrate 110, such that the middle structure 170 according to another exemplary embodiment of the present disclosure may be formed.

The middle structure 170 according to another exemplary embodiment of the present disclosure includes the upper groove 125 and the lower groove 132 formed in the sawing region 320, such that a thickness of the chipped portion may be further decreased as compared with the case in which only one of the upper groove 125 and the lower groove 132 is formed. In addition, since the upper groove 125 is formed when the circuit layer 120 is formed in the middle structure 170 and the lower groove 132 is formed when the mass 131 is formed, a separate additional process is not required. That is, in the middle structure 170 according to another exemplary embodiment of the present disclosure, a thickness of the chipped portion may be decreased without the separate additional process.

Referring to FIG. 17, the upper structure 150 and the lower structure 160 are formed.

According to another exemplary embodiment of the present disclosure, the upper structure 150 is formed on the middle structure 170, and the lower structure 160 is formed beneath the middle structure 170. See FIG. 9 with respect to a detailed description for the upper structure 150 and the lower structure 160.

Referring to FIG. 18, MEMS structures 200 are formed in a unit.

According to another exemplary embodiment of the present disclosure, a sawing process of sawing the middle structure 170, the upper structure 150, and the lower structure 160 positioned in the sawing region 320 is performed. The sawing region 320 is removed by the sawing process. Therefore, the plurality of MEMS structures 200 connected to each other are separated into the MEMS structures 200 in a unit.

Since the upper groove 125 and the lower groove 132 of the middle structure 170 are formed so as to include a portion of the sawing region 320 in the sawing process, a thickness of a portion of the sawing region 320 is decreased. Therefore, a load applied to a sawing blade performing the sawing process may be decreased, such that a defect due to back side sawing may be decreased. In addition, a thickness of the chipped portion is decreased, such that stress applied to the MEMS structure by the sawing process may be decreased. In addition, since a pad (not shown) for wiring is formed after a plasma etching process is performed, pollution of the pad (not shown) due to a plasma gas may be prevented.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A micro electro mechanical systems (MEMS) structure comprising:
a middle structure including an insulating layer, a circuit layer formed on the insulating layer, a mass formed beneath the insulating layer, and supports formed so as to be spaced apart from sides of the mass, and having corner portions of sides formed in a concave shape;
an upper structure formed so as to enclose an upper portion of the middle structure; and
a lower structure formed so as to enclose a lower portion of the middle structure.

2. The MEMS structure of claim 1, wherein the insulating layer is formed of SiO₂.

3. The MEMS structure of claim 1, wherein the upper structure includes:
an upper substrate; and
a first adhesion layer formed on a lower surface of the upper substrate and adhered to an upper surface of the middle structure.

4. The MEMS structure of claim 3, wherein the first adhesion layer is adhered to a portion of the circuit layer of the middle structure.

5. The MEMS structure of claim 1, wherein the lower structure includes:
a lower substrate; and
a second adhesion layer formed on an upper surface of the lower substrate and adhered to a lower surface of the middle structure.

6. The MEMS structure of claim 5, wherein the second adhesion layer is adhered to the supports of the middle structure.

7. A method of manufacturing an MEMS structure, comprising:
preparing a middle substrate divided into a unit region and a sawing region;
forming a circuit layer in the unit region on an upper surface of the middle substrate;
forming a middle structure by patterning a lower surface of the middle substrate to form a mass and supports in a unit region and form a lower groove in the sawing region, the supports being formed so as to be spaced apart from both sides of the mass;
forming an upper structure and a lower structure, the upper structure enclosing an upper portion of the middle structure and the lower structure enclosing a lower portion of the middle structure; and
forming an MEMS structure in a unit by removing the middle structure, the upper structure, and the lower structure in the sawing region.

8. The method of manufacturing an MEMS structure of claim 7, wherein in the preparing of the middle substrate, the middle substrate is a silicon on insulator (SOI) wafer including an insulating layer, an upper silicon layer formed on the insulating layer, and a lower silicon layer formed beneath the insulating layer.

9. The method of manufacturing an MEMS structure of claim 8, wherein in the forming of the circuit layer, the circuit layer is formed on the upper silicon layer.

10. The method of manufacturing an MEMS structure of claim 9, wherein the forming of the circuit layer further includes forming an upper groove in the upper silicon layer in the sawing region.

11. The method of manufacturing an MEMS structure of claim 10, wherein in the forming of the upper groove, the upper grooves exposes a portion of the insulating layer.

12. The method of manufacturing an MEMS structure of claim 8, wherein in the forming of the middle structure, the mass, the supports, and the lower groove are formed by patterning the lower silicon layer.

13. The method of manufacturing an MEMS structure of claim 12, wherein in the forming of the middle structure, the lower silicon layer is patterned by a plasma etching process.

14. The method of manufacturing an MEMS structure of claim 12, wherein at least one of the mass, the supports, and the lower groove exposes a portion of the insulating layer.

15. The method of manufacturing an MEMS structure of claim 7, wherein in the forming of the middle structure, the supports are formed over portions of the unit region and the sawing region.

16. The method of manufacturing an MEMS structure of claim 7, wherein in the forming of the upper structure and the lower structure, the upper structure includes an upper substrate and a first adhesion layer formed on a lower surface of the upper substrate and adhered to an upper surface of the middle structure.

17. The method of manufacturing an MEMS structure of claim 16, wherein in the forming of the upper structure and the lower structure, the first adhesion layer is adhered to the middle structure in the unit region.

18. The method of manufacturing an MEMS structure of claim 16, wherein in the forming of the upper structure and the lower structure, the first adhesion layer is adhered to the middle structure in the unit region and the sawing region adjacent to the unit region.

19. The method of manufacturing an MEMS structure of claim 7, wherein in the forming of the upper structure and the lower structure, the lower structure includes a lower substrate and a second adhesion layer formed on an upper surface of the lower substrate and adhered to a lower surface of the middle structure.

20. The method of manufacturing an MEMS structure of claim 19, wherein in the forming of the upper structure and the lower structure, the second adhesion layer is adhered to the supports.
